(19) United States
(12) Patent Application Publication
(10) Pub. No.: US 2021/0280442 A1
(43) Pub. Date: Sep. 9, 2021

(54) APPARATUS FOR SENSING WAFER LOADING STATE USING SOUND WAVE SENSOR

(71) Applicant: TSC INC., Hwaseong-si (KR)

(72) Inventors: Oh Su KIM, Suwon-si (KR); Sun Il PARK, Osan-si (KR)

(21) Appl. No.: 17/119,106

(22) Filed: Dec. 11, 2020

(30) Foreign Application Priority Data
Mar. 9, 2020 (KR) 10-2020-0029029

(51) Int. Cl. H01L 21/67; H01L 21/677

(52) U.S. Cl. CPC H01L 21/67265; H01L 21/67781

(57) ABSTRACT

Disclosed herein is an apparatus for sensing a wafer loading state using a sound wave sensor, including: a wafer loading part into which a wafer is loaded or unloaded along a slot; a sound wave sensor installed to be spaced apart from the slot, and sensing a contact sonic wave generated due to contact when the wafer is loaded or unloaded to generate real-time waveform information; and a control module confirming whether the wafer is normally loaded into the slot, wherein the control module includes: a control reception part receiving the real-time waveform information; a control memory in which a look-up table including look-up waveform information is stored; and a control determination part determining whether the wafer is normally loaded by comparing the real-time waveform information with the look-up waveform information.

### CROSS REFERENCE TO RELATED APPLICATION

This application claims the benefit of Korean Patent Application No. 10-2020-0029029, filed on Mar. 9, 2020, entitled “Apparatus for Sensing Wafer Loading State using Sound Wave Sensor”, which is hereby incorporated by reference in its entirety into this application.

### BACKGROUND

### Field

The present disclosure relates to an apparatus for sensing a wafer loading state, and more particularly, to an apparatus for sensing a state in which a wafer is loaded using a sound wave sensor for sensing sonic waves generated due to contact when the wafer is loaded into a slot.

### Description of the Related Art

A carrier, such as a front opening shipping box (FOSB) used for transferring and storing a wafer or a microelectronic device, and a front opening unified pod (FOUP) used not only for transferring and storing a wafer or a microelectronic device but also for proceeding a process, is used. Generally, the carrier includes a carrier body, and a cover for providing an ultra-clean environment inside the body by sealing the body so as to store and return the wafer. Further, the wafer is loaded into equipment such as a boat in order to proceed a predetermined process. A component for loading the wafer, such as a carrier and a boat, is referred to as a wafer loading apparatus. The wafer is supported by slots installed inside the loading apparatus and loaded or unloaded along the slots.

Meanwhile, in a process of loading or unloading the wafer into or from the sensing apparatus, it is required to clearly confirm wafer states such as the presence/absence of the wafer, positional accuracy of the wafer, and alignment of the wafer. The alignment of the wafer is to consider a deviation of the wafer deviating from one side. In Korean Patent Laid-Open Publication No. 1999-0069583, a wafer loading state is confirmed by using two sensors. However, in Korean Patent Laid-Open Publication No. 1999-0069583, positions of the sensors are fixed, and thus it is insufficient to clearly confirm all the states that may occur in the wafer, such as the presence/absence of the wafer, the positional accuracy of the wafer, and the alignment of the wafer.

### SUMMARY

An object of the present disclosure is to provide an apparatus for sensing a wafer loading state using a sound wave sensor capable of clearly confirming all states that may occur in a wafer, such as the presence/absence of the wafer, positional accuracy of the wafer, and alignment of the wafer.

According to an exemplary embodiment of the present disclosure, an apparatus for sensing a wafer loading state using a sound wave sensor, includes: a wafer loading part into which a wafer is loaded or unloaded along a slot; a sound wave sensor installed to be spaced apart from the slot, and sensing a contact sonic wave generated due to contact when the wafer is loaded or unloaded to generate real-time waveform information; and a control module confirming whether the wafer is normally loaded into the slot, wherein the control module may include a control reception part receiving the real-time waveform information; a control memory in which a look-up table including look-up waveform information is stored; and a control determination part determining whether the wafer is normally loaded by comparing the real-time waveform information with the look-up waveform information.

The sound wave sensor may include a case forming an appearance of the sound wave sensor and having a sound wave converter attachment part; a sound wave converter installed on the sound wave converter attachment part and converting the contact sonic wave into an electric signal of the contact sonic wave; a sound-absorbing material filled inside the case; and a lead wire connected to the sound wave converter and transmitting the electric signal of the contact sonic wave to the control reception part.

The sound wave converter may be formed of a piezoelectric material including at least one of PZT, lithium niobate, or crystal.

The sound wave sensor may include a case forming an appearance of the sound wave sensor, the appearance having an opening; a sonic wave focusing part formed in the opening and focusing the contact sonic wave; an amplifying part formed at a rear end of the sonic wave focusing part and amplifying the contact sonic wave; and a sound wave converter installed at a rear end of the amplifying part and converting the contact sonic wave into an electric signal of the contact sonic wave.

The sound wave sensor may further include a sound-absorbing material filled inside the case.

The sound wave sensor may further include a lead wire connected to the sound wave converter and transmitting the electric signal of the contact sonic wave to the control reception part.

The sonic wave focusing part may be formed in a funnel shape of which a diameter is to be smaller toward an inner side thereof.

The sound wave sensor may further include a narrow tube installed at the rear end of the sonic wave focusing part.

The amplifying part may be attached to the narrow tube.

The amplifying part may be driven in one of a monopole mode, a dipole mode, a quadrupole mode, or a combination thereof.

The control memory may further store sound wave sensor information, and the look-up waveform information may be classified based on the sound wave sensor information.

The control module may further include an input part for selecting a type of the sound wave sensor information.

The look-up waveform information may include normal waveform information, misaligned waveform information, and contact waveform information, and the control determination part may determine that the wafer is loaded normally when the real-time waveform information is confirmed as the normal waveform information, and determine that the wafer is loaded abnormally when the real-time waveform information is confirmed as either the misaligned waveform information or the contact waveform information.

### BRIEF DESCRIPTION OF THE DRAWINGS

FIG. 1 is a schematic diagram for describing an apparatus for sensing a wafer loading state using a sound wave sensor according to the present disclosure.

FIG. 2 is a diagram illustrating a first sound wave sensor employed in the sensing apparatus for the present disclosure, and a control module.

FIG. 3 is a diagram illustrating a second sound wave sensor employed in the sensing apparatus for the present disclosure, and a control module.

FIG. 4 is cross-sectional views illustrating cases of a wafer state sensed by the sensing apparatus for the present disclosure.

### DETAILED DESCRIPTION

Hereinafter, preferred exemplary embodiments of the present disclosure will be described in detail with reference to accompanying drawings. The exemplary embodiments described below may be modified in various other forms, and the scope of the present disclosure is not limited to the exemplary embodiment described below in detail. The exemplary embodiments of the present disclosure are provided to more completely explain the present disclosure to those skilled in the art. Meanwhile, terms indicating top, bottom, front, and the like are merely related to those shown in the drawings. In practice, the sensing apparatus may be used in any optional direction, and a spatial direction of the sensing apparatus in actual use changes depending on a direction and rotation of the sensing apparatus.

The exemplary embodiments of the present disclosure utilize the sound wave sensor for sensing the wafer loading state by sound waves to propose a sensing apparatus capable of clearly confirming all states that may occur in the wafer such as the presence/absence of the wafer, positional accuracy of the wafer, and alignment of the wafer. To this end, a specific sound wave sensor for sensing a wafer loading state and a process of confirming the wafer loading state through the sound wave sensor will be described in detail. A wafer is loaded using a slot such as a carrier and a boat, and the carrier and the boat are collectively referred to as a wafer loading part. Here, an example of the wafer loading part includes a front opening unified pod (FOUP) used not only for transferring and storing a substrate or microelectronic device, which is a carrier, but also for proceeding a process, but may include a carrier of another form within the scope of the present disclosure. In this case, a wafer refers to a substrate introduced into a process for manufacturing a microelectronic device, such as a memory, an image sensor, and an LED.

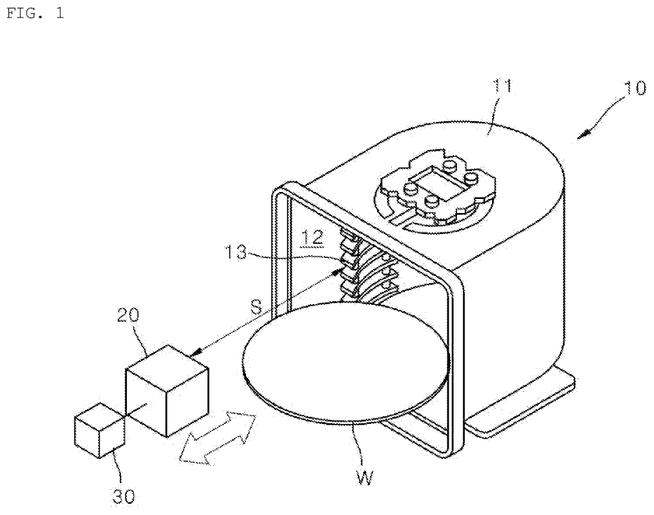

FIG. 1 is a schematic diagram for describing an apparatus for sensing a wafer loading state using a sound wave sensor according to the exemplary embodiment of the present disclosure. However, the drawings are not illustrated in a strict sense, and there may be components not illustrated in the drawings for convenience of description.

Referring to FIG. 1, the sensing apparatus according to the present disclosure includes a wafer loading part 10 loaded or unloaded with a wafer W, a sound wave sensor 20, and a control module 30. The FOUP, which is a case of the wafer loading part 10, includes a loading part body 11 that provides a loading space 12 having the wafer W loaded thereinto, and a plurality of slots 13 into which the wafer W is loaded. The FOUP, which is a carrier storing about several tens of wafers W per unit, is loaded into a lord port and is used for taking out or storing the wafer W at the time of processing the wafer W. Specifically, in order to process the wafer W, the wafer W is taken out by opening a FOUP cover. When the process is completed, the wafer W is stored by closing the cover after the wafer W is accommodated in the slot 13.

When the wafer W is loaded into or unloaded from the slot 13, the sound wave sensor 20 senses contact sonic waves generated due to contact of the wafer W with the slot 13. The contact sonic waves generated due to the contact of the wafer W with the slot 13 will be described later in detail. A position of the sound wave sensor 20 to be installed is not limited unless not interfering with the process for loading the wafer W. For example, the sound wave sensor 20 may be mounted on a robot arm carrying the wafer W or mounted on an inner wall of the lord port. A sensing distance S is preset or measured in real time by the sound wave sensor 20 so as to have a predetermined sensing distance S with the slot 13. The sensing distance S is set as a criterion for statistically processing a case of the contact sonic wave in the control module 30.

The control module 30 statistically processes the contact sonic wave generated due to the contact of the wafer W with the slot 13 in real time and compares it with a contact sonic wave stored in a look-up table to confirm a state of the wafer W. The look-up table shows a typical case of the contact sonic wave of the wafer W and the slot 13. The contact sonic wave of the present disclosure is classified into a sonic wave stored in the look-up table and a sonic wave sensed in real time. If the control module 30 confirms the state of the wafer W, the control module 30 takes an action required depending on the state. For example, if an undesirable state of the wafer W is found, the wafer W is removed from the wafer loading part 10 or loaded into the wafer loading part 10 again.

The control module 30 may include a control reception part receiving real-time waveform information; a control memory in which the look-up table including look-up waveform information is stored; and a control determination part determining whether the wafer is normally loaded by comparing the real-time waveform information with the look-up waveform information.

Here, the control memory further stores sound wave sensor information (information indicating a type of sound wave sensor), and the look-up waveform information is classified based on the sound wave sensor information. The control module further includes an input part for selecting the type of the sound wave sensor information. Further, the look-up waveform information includes normal waveform information, misaligned waveform information, and contact waveform information. When the real-time waveform information is confirmed as the normal waveform information, the control determination part may determine that the wafer is loaded normally, and when the real-time waveform information is confirmed as either the misaligned waveform information or the contact waveform information, the control determination part determines that the wafer is loaded abnormally.

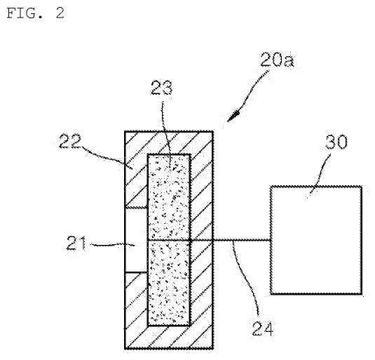

FIG. 2 is a diagram illustrating a sound wave sensor (hereinafter referred to as “first sound wave sensor 20a”) of a first exemplary embodiment employed in the sensing apparatus for the present disclosure, and the control module 30. In this case, the sensing apparatus will be referred to as FIG. 1.

Referring to FIG. 2, the first sound wave sensor 20a includes a sound wave converter 21 installed on a case 22. The sound wave converter 21 is an apparatus converting the contact sonic wave generated due to the contact of the wafer W with the slot 13 into an electric signal. The sensing distance S corresponds to a distance between the slot 13 and the sound wave converter 21. The electric signal is transmitted to the control module 30 by a lead wire 24. The control module 30 records the electric signal transmitted from the lead wire 24 as a waveform of a current or voltage changed with time. In other words, in the control module 30, a real-time waveform by which the contact sonic wave generated due to the contact is confirmed in real time and a look-up waveform stored as the look-up table exist. The control module 30 includes a comparator that compares and analyzes the real-time waveform and the look-up waveform.

The sound wave converter 21 uses various driving methods such as a voice coil driving method, a balanced armature driving method, and an electrostatic force driving method. In the voice coil driving method, the sound wave converter 21 has a voice coil and a vibration plate arranged in a magnetic field, and generates compressional sonic waves in the air by vibrating the vibration plate using a Lorentz force which is generated in the voice coil by an electric signal. The sound wave converter 21 may utilize a piezoelectric material. Examples of the piezoelectric material include, but are not necessarily limited to, PZT, lithium niobate, crystal, and a combination thereof. In addition to the proposed methods, the sound wave converter 21 may use other methods within the scope of the present disclosure.

In some cases, the inside of the case 22 may be filled with a sound-absorbing material 23. The sound-absorbing material 23 is a material used for absorbing contact sonic waves, and a porous sound-absorbing material is good. The porous sound-absorbing material has small bubbles or tube-shaped pores on a surface and inside thereof, and is absorbed by converting sonic wave energy into thermal energy due to friction generated by vibrating the air in the pores by the contact sonic wave. The sound-absorbing material 23 prevents the sound wave converter 21 from being deformed due to impact or deviated from its original position.

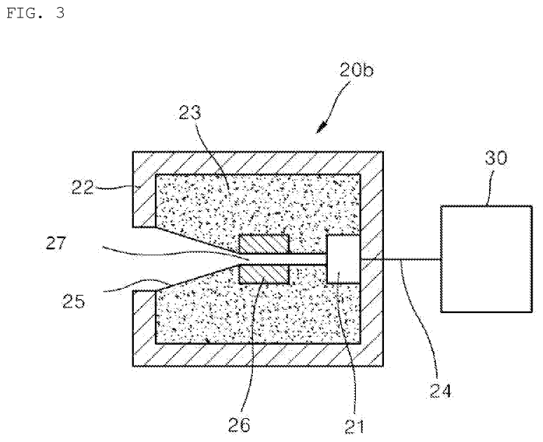

FIG. 3 is a diagram illustrating a sound wave sensor (hereinafter referred to as “second sound wave sensor 20b”) of a second exemplary embodiment employed in the sensing apparatus for the present disclosure, and the control module 30. Here, the second sound wave sensor 20b is the same as the first sound wave sensor 20a except for collecting and amplifying the sonic waves. Accordingly, detailed description of the same reference numerals will be omitted. In this case, the sensing apparatus will be referred to as FIG. 1.

Referring to FIG. 3, the second sound wave sensor 20b includes the sound wave converter 21 installed on the case 22, a sonic wave focusing part 25, and an amplifying part 26. The sonic wave focusing part 25 is formed in a funnel shape, and a rear end thereof is connected with a narrow tube 27. The sonic wave focusing part 25 may be fabricated from glass, metal, plastic, or a combination thereof. Among them, stainless steel is a suitable material.

The sonic wave focusing part 25 collects and focuses the contact sonic waves arriving from the wafer loading part 10. The collected contact sonic waves are focused due to a shape of the sonic wave focusing part 25, and transmitted to the narrow tube 27. The narrow tube 27 is connected to a part of the sonic wave focusing part 25 having the narrowest width. When the contact sonic wave transmitted to the narrow tube 27 overlaps a sonic wave having the same frequency as the contact sonic wave, a physical phenomenon such as interference in which sound becomes strong while overlapping a compression part of the contact sonic wave with a compression part of the sonic wave or interference in which sound becomes weak while overlapping the compression part of the contact sonic wave with an expansion part of the sonic wave, occurs. The narrow tube 27 refers to a channel having a shape selected from circles such as an oval and an eccentric circle, and polygon such as a rectangle. Inner walls of a capillary do not need to have the same shape as outer walls thereof. For example, the narrow tube 27 may have a circular-shaped inner wall and a rectangular-shaped outer wall.

In some cases, the amplifying part 26 may be attached to an outer circumference of the narrow tube 27. The amplifying part 26 is a device that causes vibration, such as a piezoelectric device. When the amplifying part 26 generates vibrations, the contact sonic waves in the narrow tube 27 are amplified. FIG. 3 illustrates a form in which the narrow tube 27 is operated in a dipole mode in which the sonic wave is focused on a central axis of the narrow tube 27 by using two amplifying part 26. However, the narrow tube 27 may be applied to all vibration modes including a monopole mode, a multipole mode such as a dipole mode and a quadrupole mode, or a combination thereof. For example, the dipole mode is driven by the two amplifying parts 26 attached to opposite walls of the narrow tube 27 and driven with a 180-degree phase difference. The quadrupole mode is driven by attaching the amplifying parts 26 at orthogonal positions deviated from 90 degrees from each other, resulting in a phase difference. On the other hand, the narrow tube 27 may be driven in different modes by changing the positions of the amplifying parts 26 attached to the narrow tube 27.

The amplifying part 26 is formed of a piezoelectric material, which is preferable. Examples of the piezoelectric material include, but are not necessarily limited to, PZT, lithium niobate, crystal, and a combination thereof. Further, the amplifying part 26 may be a vibration generator composed of a Langevin transducer or other materials, or an apparatus capable of generating a vibration or surface displacement of the narrow tube 27. According to the exemplary embodiment of the present disclosure, the amplifying part 26 includes an acoustically focused line drive capillary that yields a larger sound source aperture than a standard line contact.

Sound is one of the waves, and sound in a fluid such as the air is a pressure wave, that is, a wave that vibrates in a medium and propagates due to variation of pressure. The sound in the air is shown in a form in which a region having a high air density and a region having a low air density are repeated in a moment. Such a repeated pressure difference is transmitted to the sonic wave focusing part 25. The sound and the sonic wave have the same physical meaning, but the sound mainly refers to a sonic wave that may be heard, and means a sonic wave in gas or liquid. Further, the sound means a sonic wave that is heard physiologically or a recognized sonic wave, whereas the sonic wave means a physical and mechanical wave that almost entirely propagates while vibrating in the medium. Accordingly, the contact sonic wave according to the exemplary embodiment of the present disclosure refers to a physical wave.

A magnitude of the contact sonic wave is closely related to an amount of energy transmitted by the sonic wave per unit area and unit time. That is, the magnitude of the contact sonic wave is denoted as P/S, P is a power representing energy transmitted per unit time, and S is an area where the energy is transmitted. The energy transmitted by the contact sonic wave is proportional to an amplitude, and is thus given by I=½[ρv(2πf)²A². Here, ρ represents an air density, v represents a transmission velocity of the contact sonic wave, f represents a vibration frequency, and A represents an amplitude of the pressure wave. The transmitted energy of the sound corresponding to the largest contact sonic wave that the person may feel is about 10 W/m², which may be the transmitted energy of the sound of 10 trillion times more than that of the smallest contact sonic wave. Therefore, a unit of the magnitude of the sound corresponding to the contact sonic wave that the person tolerates is not denoted as I, and uses dB (decibel) according to a logarithmic scale.

When the contact sonic wave transmitted to the narrow tube 27 overlaps a contact sonic wave having the same frequency as the contact sonic wave, a physical phenomenon, such as constructive interference in which sound becomes strong while overlapping a compression part of the contact sonic wave transmitted to the narrow tube 27 with a compression part of the contact sonic wave having the same frequency or destructive interference in which sound becomes weak while overlapping the compression part of the contact sonic wave transmitted to the narrow tube 27 with the expansion part of the contact sonic wave having the same frequency, occurs. The amplifying part 26 according to the exemplary embodiment of the present disclosure applies vibrations, thereby causing the constructive interference of the contact sonic wave to amplify the contact sonic wave. The vibration of the amplifying part 26 may be appropriately adjusted depending on a size or specification of the second sound wave sensor 20b of the present disclosure, an environment where the second sound wave sensor is used, and a channel diameter or length of the narrow tube 27.

The contact sonic wave generated through the sonic wave focusing part 25 is converted into an electric signal in the sound wave converter 21. The sonic wave focusing part 25 amplifies the contact sonic wave generated from the contact of the wafer W with the slot 13. When the contact sonic wave is amplified, a micro contact sonic wave in the contact sonic wave generated from the contact may also be sensed. When the micro contact sonic wave is sensed, the state of the wafer W generated from the contact of the wafer W with the slot 13 may be confirmed in more various patterns. Specifically, when the contact sonic wave is amplified, the electric signal transmitted from the sound wave converter 21 is amplified as the waveform of the current or voltage that changes with time.

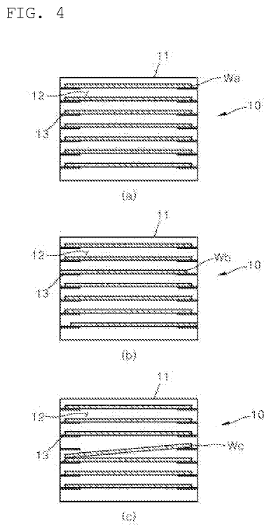

Obviously, even though the sonic wave is partially lost due to the destructive interference, the waveform of the current or voltage is amplified. Therefore, the state of the wafer W may be confirmed more clearly. FIG. 4 is cross-sectional views illustrating cases of a state of the wafer W sensed by the sensing apparatus according to the exemplary embodiment of the present disclosure. Some cases are shown herein, but there may be more cases within the scope of the present disclosure. In this case, the sensing apparatus will be referred to as FIG. 1.

Referring to FIG. 4, three cases Wa, Wb, and Wc for the states of the wafer W are presented as examples. The first case Wa is a state in which the wafer W is loaded at a top of the wafer loading part 10, the second case Wb is a state in which the wafer W is deviated from the top and loaded into the slot 13 while bringing the wafer W into contact with the inner wall of the wafer loading part 10, and the third case Wc is a state in which one side of the wafer W is loaded into the wrong slot 13. The second case Wb shows that the wafer is loaded in a misaligned state. Assuming a process of loading the wafer W, a first contact sonic wave generated due to the contact of the wafer W with the slot 13 in the first case Wa, a second contact sonic wave generated due to the contact of the wafer W with the inner wall of the wafer loading part 10 together with the slot 13 in the second case Wb, and a third contact sonic wave generated due to the contact of the wafer W with a wrong slot 13 together with the slot 13 in the third case Wc are generated.

Meanwhile, look-up waveforms of the three cases Wa, Wb, and Wc stored in the look-up table vary depending on the first and second sound wave sensors 20a and 20b. Further, if the amplifying part 26 is attached to the second sound wave sensor 20b, the look-up waveform may vary. The look-up waveform may be determined depending on which one of the sound wave sensors 20a and 20b according to the exemplary embodiment of the present disclosure is selected. The sound wave sensors 20a and 20b may be selected depending on a type of process, a surrounding environment, a surrounding noise level, or the like. In particular, the look-up waveform may show a typical case according to the real-time sensing distance S.

According to the apparatus for sensing a wafer loading state using a sound wave sensor of the present disclosure, the sound wave sensor for sensing the wafer loading state by sound waves is utilized, such that it is possible to clearly confirm all the states that may occur in the wafer such as the presence/absence of the wafer, the positional accuracy of the wafer, and the alignment of the wafer.

While the present disclosure has been described in detail with reference to the preferred exemplary embodiments, it will be understood by those of ordinary skill in the art that various changes in form and details may be made therein without departing from the spirit and scope of the present disclosure.

What is claimed is:

1. An apparatus for sensing a wafer loading state using a sound wave sensor, the apparatus comprising:
a wafer loading part into which a wafer is loaded or unloaded along a slot;
a sound wave sensor installed to be spaced apart from the slot, and sensing a contact sonic wave generated due to contact when the wafer is loaded or unloaded to generate real-time waveform information; and
a control module confirming whether the wafer is normally loaded into the slot,
wherein the control module includes:
a control reception part receiving the real-time waveform information;
a control memory in which a look-up table including look-up waveform information is stored; and
a control determination part determining whether the wafer is normally loaded by comparing the real-time waveform information with the look-up waveform information.

2. The apparatus of claim 1, wherein the sound wave sensor includes:
a case forming an appearance of the sound wave sensor and having a sound wave converter attachment part;
a sound wave converter installed on the sound wave converter attachment part and converting the contact sonic wave into an electric signal of the contact sonic wave;
a sound-absorbing material filled inside the case; and
a lead wire connected to the sound wave converter and transmitting the electric signal of the contact sonic wave to the control reception part.

3. The apparatus of claim 2, wherein the sound wave converter is formed of a piezoelectric material including at least one of PZT, lithium niobate, or crystal.

4. The apparatus of claim 1, wherein the sound wave sensor includes:
a case forming an appearance of the sound wave sensor, the appearance having an opening;
a sonic wave focusing part formed in the opening and focusing the contact sonic wave;
an amplifying part formed at a rear end of the sonic wave focusing part and amplifying the contact sonic wave; and
a sound wave converter installed at a rear end of the amplifying part and converting the contact sonic wave into an electric signal of the contact sonic wave.

5. The apparatus of claim 4, further comprising a sound-absorbing material filled inside the case.

6. The apparatus of claim 5, wherein the sound wave sensor further includes a lead wire connected to the sound wave converter and transmitting the electric signal of the contact sonic wave to the control reception part.

7. The apparatus of claim 4, wherein the sonic wave focusing part is formed in a funnel shape of which a diameter is to be smaller toward an inner side thereof.

8. The apparatus of claim 7, wherein the sound wave sensor further includes a narrow tube installed at the rear end of the sonic wave focusing part.

9. The apparatus of claim 8, wherein the amplifying part is attached to the narrow tube.

10. The apparatus of claim 9, wherein the amplifying part is driven in one of a monopole mode, a dipole mode, a quadrupole mode, or a combination thereof.

11. The apparatus of claim 1, wherein the control memory further stores sound wave sensor information, and
the look-up waveform information is classified based on the sound wave sensor information.

12. The apparatus of claim 11, wherein the control module further includes an input part for selecting a type of the sound wave sensor information.

13. The apparatus of claim 1, wherein the look-up waveform information includes normal waveform information, misaligned waveform information, and contact waveform information, and
the control determination part determines that the wafer is loaded normally when the real-time waveform information is confirmed as the normal waveform information, and determines that the wafer is loaded abnormally when the real-time waveform information is confirmed as either the misaligned waveform information or the contact waveform information.
